(19) United States
(12) Patent Application Publication
(10) Pub. No.: US 2013/0181181 A1
(43) Pub. Date: Jul. 18, 2013

(54) MIIIM DIODE HAVING LANTHANUM OXIDE

(71) Applicant: SanDisk 3D LLC, Milpitas, CA (US)

(72) Inventors: Deepak C. Sekar, San Jose, CA (US); Tanmay Kumar, Pleasanton, CA (US); Peter Rabkin, Cupertino, CA (US); Xiying Chen Costa, San Jose, CA (US)

(73) Assignee: SANDISK 3D LLC, Milpitas, CA (US)

(21) Appl. No.: 13/787,505

(22) Filed: Mar. 6, 2013

Related U.S. Application Data
(62) Division of application No. 12/240,766, filed on Sep. 29, 2008.

(51) Int. Cl. H01L 45/00

(52) U.S. Cl. CPC H01L 45/145
USPC 257/2; 438/381

(57) ABSTRACT

A MIIIM diode and method of fabricating are disclosed. In one aspect, the MIIIM diode comprises a first metal electrode, a first region comprising a first insulator material having an interface with the first metal electrode, a second region comprising a second insulator material having an interface with the first insulator material, a third region comprising a third insulator material having an interface with the second insulator material, and a second metal electrode having an interface with the third insulator material. At least one of the first, second, or third insulator materials is lanthanum oxide.

### CLAIM OF PRIORITY

This application is a divisional application of U.S. patent application Ser. No. 12/240,766, entitled “METAL-INSULATOR DIODE HAVING DOPED INSULATOR”, by Sekar et al., filed Sep. 29, 2008, and incorporated herein by reference in its entirety.

### CROSS-REFERENCE TO RELATED APPLICATIONS

The following related applications, filed on even date herewith, are cross-referenced and incorporated by reference herein in their entirety:

U.S. patent application Ser. No. 12/240,785, now U.S. Pat. No. 7,969,011, entitled “MIIM DIODES HAVING STACKED STRUCTURE”; and

U.S. patent application Ser. No. 12/240,758, now U.S. Pat. No. 7,615,439, entitled “DAMASCENE PROCESS FOR CARBON MEMORY ELEMENT WITH MIIM DIODE.”

### BACKGROUND OF THE INVENTION

1. Field of the Invention

Embodiments in accordance with the present disclosure are directed to integrated circuits containing non-volatile memory cell arrays and particularly those arrays incorporating passive element memory cells.

2. Description of the Related Art

Materials having a detectable level of change in state, such as a resistance or phase change, are used to form various types of non-volatile semiconductor based memory devices. For example, simple anti-fuses are often used for binary data storage in one time field programmable (OTP) memory arrays by assigning a lower resistance initial physical state of a memory cell to a first logical state such as logical ‘0,’ and assigning a higher resistance physical state of the element to a second logical state such as logical ‘1.’ Other logical data assignments to physical states may also be used. Some materials can be reset back to a higher resistance state after being set from an initial state to a lower resistance state. These types of materials can be used to form re-writable memory cells. Multiple levels of detectable resistance in materials can further be used to form multi-state devices which may or may not be re-writable.

Materials having a memory effect such as a detectable level of resistance are often placed in series with a steering element to form a memory device. Diodes or other devices having a non-linear conduction current are typically used as the steering element. In many implementations, a set of word lines and bit lines are arranged in a substantially perpendicular configuration with a memory cell at the intersection of each word line and bit line. Two-terminal memory cells can be constructed at the intersections with one terminal (e.g., terminal portion of the cell or separate layer of the cell) in contact with the conductor forming the respective word line and another terminal in contact with the conductor forming the respective bit line.

One type of diode that might be used for the steering element is a metal insulator metal diode. Metal insulator diodes may have more than one insulating layer. Thus, as the term is used herein “metal-insulator diode” includes diodes with one or more insulator layers. For example, one configuration is a metal-insulator-insulator-metal diode (MIIM diode).

One problem with MIIM diodes is getting a sufficiently high current when under forward bias given the relatively small scale of structures that is desired. Another problem with MIIM diodes is that the breakdown voltage is typically too low. The breakdown voltage is generally defined as the largest reverse voltage that can be applied without causing an exponential increase in the current in the diode. A third problem with MIIM diodes is that rectification ratios are too low. The rectification ratio is defined as the ratio of the forward current to the reverse current at voltages that are equal in magnitude but opposite in sign. Still another problem is the process complexity of fabricating MIIM diodes. For example, in order to obtain diodes with good on current, low breakdown voltages, and high rectification ratios, it can be desirable to form the diode with thin dielectric regions. However, fabricating such thin dielectrics presents challenges.

### SUMMARY OF THE INVENTION

A metal-insulator diode is disclosed. In one aspect, the metal-insulator diode comprises a first electrode comprising a first metal, a first region comprising a first insulating material, a second region comprising a second insulating material, and a second electrode comprising a second metal. The first region and the second region reside between the first electrode and the second electrode. The second insulating material is doped with nitrogen. Note that the second insulating material may have an interface with either the first electrode or the second electrode. In one aspect, an interface between the first insulating material and the first metal has a first conduction band offset, and an interface between the second insulating material and the second metal has a second conduction band offset. The second conduction band offset is greater than the first conduction band offset. In one embodiment, a memory element is in electrical contact with the diode.

Another embodiment is metal-insulator diode that is doped with a material that improves properties of the diode. The diode has a first electrode comprising a first metal and a first region comprising a first insulating material. The first insulating material has a first interface with the first metal, and the first interface has a first conduction band offset. The diode further has a second region comprising a second insulating material. The second insulating material is doped with a doping material. The diode also has a second electrode comprising a second metal. The second insulating material has a second interface with the second metal, and the second interface has a second conduction band offset. The second conduction band offset is greater than the first conduction band offset. In one aspect, the doping material increases the on current of the diode. In one aspect, the doping material in the second insulator material incorporates traps into the second region.

One embodiment is a metal-insulator diode having three insulating layers. At least one of the three insulating layers comprises lanthanum oxide. In one embodiment, at least one of the three insulating layers comprises hafnium oxide.

One embodiment is a method for forming a metal-insulator diode. The method includes forming a first electrode comprising a first metal, forming a first insulating region comprising a first insulating material, forming a second insulating region comprising a second insulating material, doping the second insulating material with nitrogen, and forming a second electrode comprising a second metal. The first region and the second region reside between the first electrode and the second electrode. Note that the third region that has the second insulating material can be formed either prior to or after forming the second region that has the first insulating material.

### BRIEF DESCRIPTION OF THE DRAWINGS

FIG. 1 depicts an exemplary non-volatile memory cell in accordance with one embodiment.

FIG. 2 depicts one embodiment of different regions of a MIIM diode.

FIG. 3A, FIG. 3B, and FIG. 3C depict energy band diagrams of one embodiment of the MIIM diode to demonstrate principles of operation.

FIG. 4 is a graph of conduction band barrier height versus nitrogen (and oxygen) content for compounds comprising silicon, oxygen, and nitrogen.

FIG. 5 depicts a graph showing current versus voltage curves for a MIIM diode that was doped with nitrogen and a MIIM diode that was not doped.

FIG. 6A and FIG. 6B depict various properties of the MIIM diodes associated with the curves FIG. 5.

FIG. 7 depicts one embodiment of a MIIIM diode having a region of lanthanum oxide (La₂O₃).

FIG. 8 depicts a graph showing current versus voltage curves for a several MIIM diodes.

FIG. 9 is a flowchart illustrating one embodiment of a process of fabricating a MIIM diode.

FIG. 10A depicts a cross section of one embodiment of a MIIM diode taken along line B-B′ of FIG. 10B.

FIG. 10B depicts a cross section of the embodiment of FIG. 10A taken along line A-A′ of FIG. 10A.

FIG. 11A and FIG. 11B are respective perspective and cross-sectional views of a three-dimensional memory array in accordance with one embodiment.

FIG. 12 is block diagram of a non-volatile memory system in accordance with one embodiment.

FIG. 13 is a simplified circuit diagram of a memory array in accordance with one embodiment.

### DETAILED DESCRIPTION

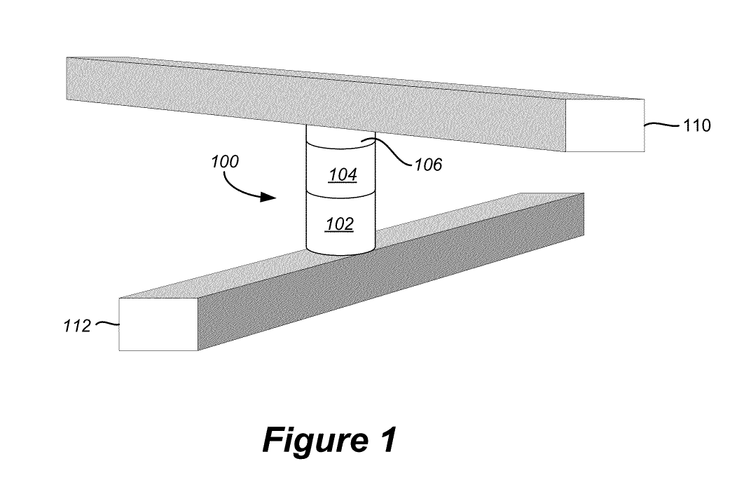

FIG. 1 depicts an exemplary structure for a non-volatile memory cell that can be used in accordance with embodiments of the present disclosure. A two-terminal memory cell 100 as depicted in FIG. 1 includes a first terminal portion connected to a first conductor 110 and a second terminal portion connected to a second conductor 112. The memory cell includes a steering element 102 in series with a state change element 104 and an anti-fuse 106 to provide non-volatile data storage. The steering element can take the form of any suitable device exhibiting a nonlinear conduction current characteristic such as a simple diode. Various embodiments of MIIM diodes disclosed herein can be used to implement the steering element. The state change element 104 will vary by embodiment and can include numerous types of materials to store data through representative physical states. State change element 104 can include resistance change materials, phase change resistive materials, etc. For example, a semiconductor or other material having at least two levels of detectable resistance change (e.g., low to high and high to low) is used in one embodiment to form a passive storage element 100.

Examples of suitable materials for state change element 104 include, but are not limited to doped semiconductors (e.g., polycrystalline silicon, more commonly polysilicon), transition metal oxides, complex metal oxides, programmable metallization connections, phase change resistive elements, organic material variable resistors, carbon polymer films, doped chalcogenide glass, and Schottky barrier diodes containing mobile atoms that change resistance. The resistivity of these materials in some cases may only be switched in a first direction (e.g., high to low), while in others, the resistivity may be switched from a first level (e.g., higher resistance) to a second level (e.g., lower resistance), and then switched back toward the first resistivity level.

In one embodiment, the state change element 104 is Ge₂Sb₂Te₅ (GST). GST has a property of reversible phase change from crystalline to amorphous-allowing two levels per cell. However, quasi-amorphous and quasi-crystalline phases may also be used to allow additional levels per cell with GST.

In some embodiments, the state change element 104 is formed from a carbon material. A state change element 104 that is formed from carbon may comprise any combination of amorphous and graphitic carbon. In one aspect, the carbon is deposited as a carbon film. However, it is not required that a carbon state change element be a carbon film. In one aspect, the state change element 104 is a carbon nanotube. One type of carbon nanotube stores a charge based on position of a “guest” molecule in the nanotube. The position of the guest molecule, which remains stable even without energy supplied to the memory cell, modifies the electronic properties of the nanotube. One stable position of the guest molecule results in a high current, whereas the current is measurably lower in at least one other position.

By assigning logical data values to the various levels of resistance that can be set and read from resistance change element 104, memory cell 100 can provide reliable data read/write capabilities. Anti-fuse 106 can further provide resistance state change abilities that can be exploited for non-volatile data storage. An anti-fuse is manufactured in a high resistance state and can be popped or fused to a lower resistance state. An anti-fuse is typically non-conductive in its initial state and exhibits high conductivity with low resistance in its popped or fused state. As a discreet device or element may have a resistance and different resistance states, the terms resistivity and resistivity state are used to refer to the properties of materials themselves. Thus, while a resistance change element or device may have resistance states, a resistivity change material may have resistivity states.

Anti-fuse 106 can provide benefits to memory cell 100 beyond its state change ability. For example, an anti-fuse can serve to set the on-resistance of the memory cell in at an appropriate level relative to the read-write circuitry associated with the cell. These circuits are typically used to pop the anti-fuse and have an associated resistance. Because these circuits drive the voltages and current levels to pop the anti-fuse, the anti-fuse tends to set the memory cell in an appropriate on-resistance state for these same circuits during later operations.

A range of resistance values can be assigned to a physical data state to accommodate differences amongst devices as well as variations within devices after set and reset cycling. The terms set and reset are typically used, respectively, to refer to the process of changing an element from a high resistance physical state to a low resistance physical state (set) and changing an element from a low resistance physical state to a higher resistance physical state (reset). Embodiments in accordance with the present disclosure can be used to set memory cells to a lower resistance state or to reset memory cells to a higher resistance state. While specific examples may be provided with respect to set or reset operations, it will be appreciated that these are mere examples and that the disclosure is not so limited.

Various types of suitable state change elements are described in U.S. Pat. No. 6,034,882 entitled “Vertically Stacked Field Programmable Non-volatile Memory and Method of Fabrication.” Various other types of state change elements may be used, including those described in U.S. Pat. No. 6,420,215 entitled “Three Dimensional Memory Array and Method of fabrication,” and U.S. Pat. No. 6,631,085, entitled “Three-Dimensional Memory Array Incorporating Serial Chain Diode Stack,” all hereby incorporated by reference in their entirety.

It will be appreciated that other types of two-terminal non-volatile memory cells can be used in embodiments. For example, one embodiment does not have an anti-fuse 106 and merely includes state change element 104 and steering element 102. Other embodiments may include additional state change elements in place of or in addition to the anti-fuse.

Conductors 110 and 112 are typically orthogonal to one another and form array terminal lines for accessing an array of memory cells 100. The array terminal lines (also called array lines) at one layer may be termed word lines or X-lines. The array lines at a vertically adjacent layer may be termed bit lines or Y-lines. A memory cell can be formed at the projected intersection of each word line and each bit line, and connected between the respective intersecting word line and bit line as shown for the formation of memory cell 100. A three-dimensional memory array which has at least two levels of memory cells (i.e., two memory planes) may utilize more than one layer of word lines and/or more than one layer of bit lines. A monolithic three dimensional memory array is one in which multiple memory levels are formed above a single substrate, such as a wafer, with no intervening substrates.

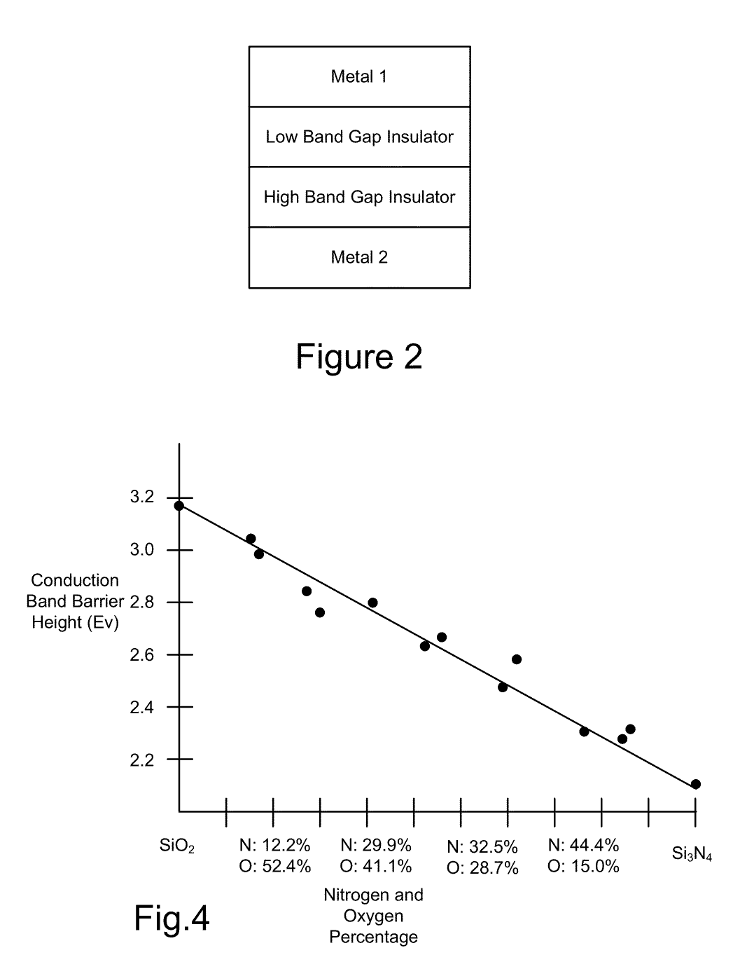

FIG. 2 depicts one embodiment of different regions of a MIIM diode. The MIIM diode may be used to implement the steering element 102 portion of the memory cell 100. The MIIM diode comprises two separate metal regions and two insulating regions. Note that in some embodiments, the diode has more than two insulating regions. For example, a metal-insulator diode with three insulating regions (MIIIM diode) is also disclosed herein.

The first and second metal regions may serve as the anode and the cathode of the diode. An example material for metal 1 and metal 2 is titanium nitride (TiN). Other example materials for the anode and cathode are n+ doped polysilicon for metal 1 and p+ doped polysilicon for metal 2. Thus, the term “metal” when used with respect to a metal-insulator diode includes doped polysilicon.

One insulating layer is a “low-bandgap” insulator. The other insulating layer is a “high-bandgap” insulator. The bandgap of the insulator refers to the difference in energy between the top of the valance band and the bottom of the conduction band for the insulator. The terms “low” and “high” are used relative to one another in that the “low-bandgap” insulator has a smaller energy difference between its valence and conduction band than does the “high-bandgap” insulator. An example material for the low bandgap material is hafnium dioxide (HfO₂). An example material for the high bandgap material is silicon dioxide (SiO₂). Other suitable insulators include, but are not limited to, lanthanum oxide (La₂O₃), aluminum oxide (Al₂O₃), silicon-oxynitride (Si₂OₓN_{y}), and hafnium silicate (HfSixOy).

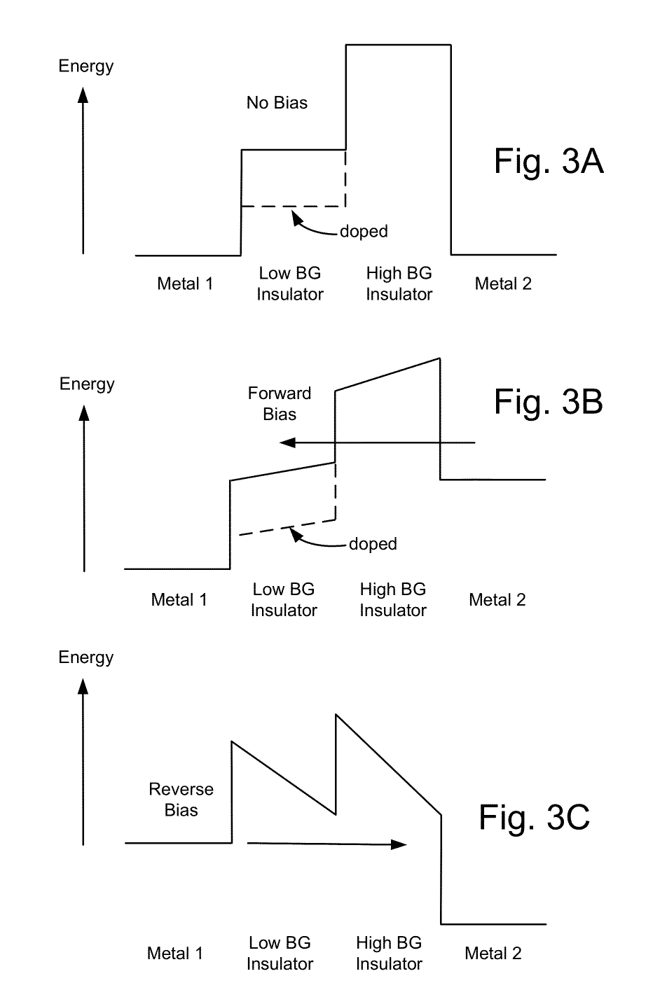

FIGS. 3A-3C depict energy band diagrams of one embodiment of the MIIM diode to demonstrate principles of operation. FIG. 3A depicts an energy band diagram for the MIIM diode with no bias applied. Note that the energy offset between the high bandgap insulator and metal 2 is substantially greater than the energy offset between the low bandgap insulator and metal 1.

FIG. 3B depicts an energy band diagram for the MIIM diode under forward bias. In this case, the applied voltage increases the energy level of metal 2 relative to metal 1. In this example, the energy level of metal 2 has been raised to about the same level as the low band gap insulator. Therefore, the low bandgap insulator does not present much of a barrier to electron flow. However, the high bandgap insulator presents a significant barrier to electron flow. Even so, some electrons are able to tunnel through the barrier of the high bandgap insulator via quantum mechanical tunneling. That is, although the energy level of the high bandgap material is significantly higher than that of metal 2, there is some probability that a given electron will be able to tunnel from metal 2 through the high bandgap insulator. The low bandgap insulator then does not present much of a barrier to prevent the electron from reaching metal 1. The sloping of the energy levels of the insulators is a result of the applied forward bias voltage.

FIG. 3C depicts an energy band diagram of the MIIM diode under reverse bias. In this case, the applied voltage increases the energy level of metal 1 relative to metal 2. Note that the reverse bias voltage also affects the slope and energy level of the insulators. In particular, there is still a substantial energy offset at the interface between metal 1 and the low bandgap insulator. Thus, the low bandgap insulator presents a substantial barrier to electrons. The high band gap insulator also presents a substantial barrier to electron flow. Thus, the electrons must tunnel through a region having the width of both insulators. While some electrons will by probability tunnel through the insulators to metal 2, the magnitude of the reverse bias current will be much smaller than the magnitude of the forward bias current.

In some embodiments, at least one of the insulating layers is doped with a material that helps to increase the on-current of the diode. One technique for increasing the on-current is to lower the conduction band offset between one of the insulators and its adjacent metal. In one such embodiment, at least one of the insulating regions is doped with nitrogen. As an example, a silicon dioxide region is doped with nitrogen. However, a different insulator material could also be doped with nitrogen or another dopant. Doping with nitrogen may serve to lower the conduction band barrier height of the insulator. This in turn lowers the conduction band offset between the insulator and the adjacent metal, which may increase the diode's on current.

FIG. 4 is a graph of conduction band barrier height versus nitrogen (and oxygen) content for compounds comprising silicon, oxygen, and nitrogen. The y-axis corresponds to pure silicon dioxide (no nitrogen). The rightmost point on the graph corresponds to replacing all of the oxygen with nitrogen (Si₃N₄). Points in between correspond to compounds having a given nitrogen and oxygen concentration (and silicon). For example, one point corresponds to a compound having 12.2% nitrogen, 52.4% oxygen with the remaining portion being silicon. The graph shows that with no nitrogen in the silicon dioxide the conduction band barrier height is at its greatest (about 3.2 eV). As the amount of nitrogen increases, the conduction band barrier height decreases. When nitrogen content is the greatest, the conduction band barrier height has dropped to about 2.2 eV.

Thus, if Si₃N₄ has an interface with a metal, the conduction band offset between the Si₃N₄ and the metal will be about 1 eV less than the conduction band offset between SiO₂ having an interface with the metal. Now consider an example in which the low band gap insulator of FIG. 2 is doped with nitrogen. The net result would be a lowering of the energy level of the low band gap insulator. Referring now to FIG. 3A, the energy level of the low bandgap insulator will be lower, as depicted by the dashed line. Referring now to FIG. 3B, a nitrogen doped low bandgap insulator will present slightly less of a barrier to electrons, as depicted by the dashed line. Thus, electrons are able to flow more easily through the low band gap material.

In effect, a doped low band gap insulator of a given thickness may act somewhat like an undoped low bandgap insulator that is substantially thinner. That is, a thinner insulator tends to present less of a barrier to electron flow. However, creating very thin insulators can be difficult. Also note that for the reverse bias case of FIG. 3C, even a doped low band gap insulator (dashed line not depicted) may present a significant barrier to electron flow. Thus, the doping of the low band gap insulator may tend to increase forward bias current more than it tends to increase reverse bias current.

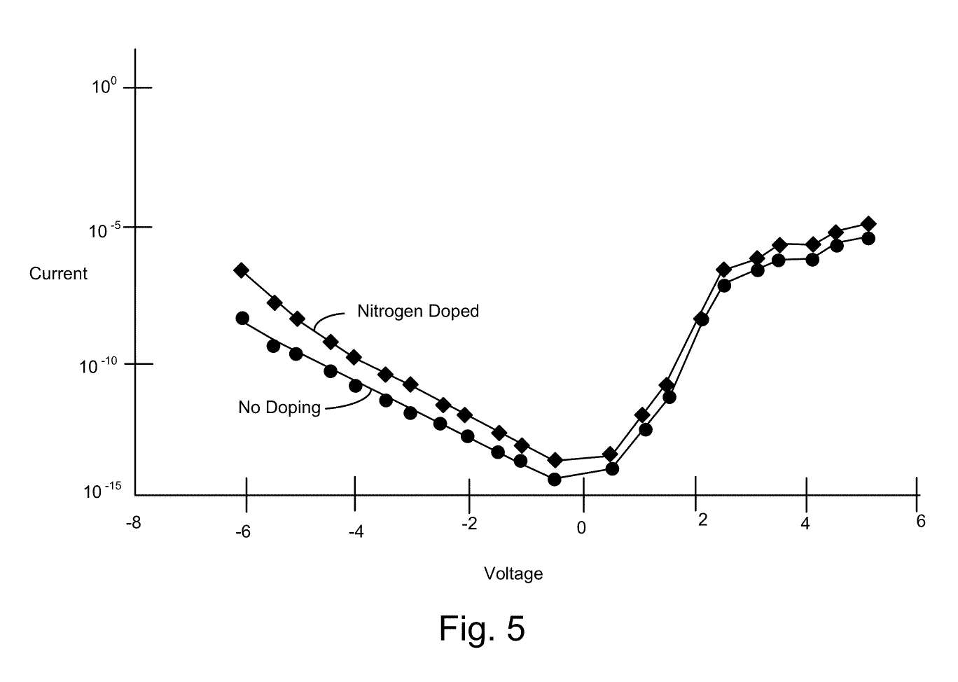

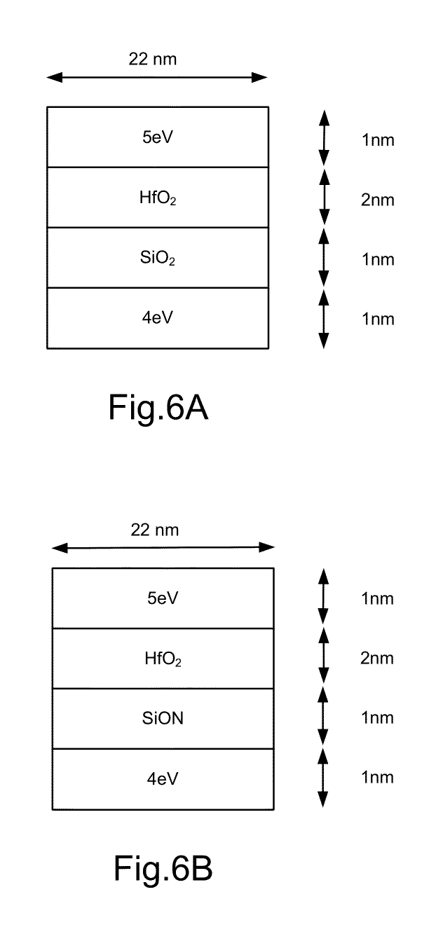

FIG. 5 depicts results of a simulation performed for a MIIM diode that was doped with nitrogen and a MIIM diode that was not doped. FIGS. 6A and 6B depict various properties of the MIIM diodes upon which the simulation was based. FIG. 6A shows a configuration for an undoped MIIM diode. The MIIM diode has electrodes with 4 eV and 5 eV work functions. Each electrode is 1 nanometer thick. The insulating region near the 5 eV electrode is hafnium dioxide and is 2 nanometers thick. The insulating region near the 4 eV electrode is silicon dioxide and is 1 nanometer thick. The MIIM diode is 22 nm wide.

FIG. 6B shows a configuration for a doped MIIM diode. The MIIM diode has electrodes with 4 eV and 5 eV work functions. Each electrode is 1 nanometer thick. The insulating region near the 5 eV electrode is hafnium dioxide and is 2 nanometers thick. The insulating region near the 4 eV electrode is doped silicon dioxide (SiON) and is 1 nanometer thick. The percentage of nitrogen in the SiON for the simulation whose results are depicted in FIG. 5 is 16 percent. The MIIM diode is 22 nm wide. Thus, the two MIIM diodes are similar in all respects except for the nitrogen doping in the silicon dioxide region.

Referring now to FIG. 5, two curves of diode current versus voltage are depicted. The nitrogen doped MIIM diode has a higher on current. That is, when the voltage is positive, the current of the doped MIIM diode is significantly higher than the current for the undoped diode. Note that the scale for the diode current is logarithmic.

Table 1 shows the rectification factor (or ratio), the on-current, and the leakage current for the two diodes of the simulation of FIG. 5.

TABLE 1

| | Undoped | Doped with Nitrogen |
|---|---|---|
| Rectification | 1.7 × 10⁵ | 6.8 × 10⁴ |
| Ratio | at +−2.5 V | at +−3.5 V |
| On Current | 3 × 10⁻⁶ | 10.2 × 10⁻⁶ |
| At 5 V | | |
| Leakage | 0.19 × 10⁻⁹ | 3.3 × 10⁻⁹ |
| Current at −5 V | | |

Doping of nitrogen into silicon dioxide may introduce traps in the silicon dioxide. The results in FIG. 5 and Table 1 do not factor in the possible introduction of traps. Traps may increase the on-current even more than the simulation results. Another possible benefit of nitrogen doping is a reduction of oxidation of the metal electrode that is in contact with the silicon dioxide insulator.

In order to obtain low leakage current for MIIM diodes, a high dielectric material may be used for the low bandgap insulator. A material that has a low electron affinity may also be selected to help obtain a low leakage current. The electron affinity is the energy required to detach an electron from a singly charged negative ion. One possible material that may be used because it has a relatively low electron affinity and relatively high dielectric constant is lanthanum oxide (La₂O₃). Table 2 shows the electron affinity and dielectric constant for various materials. Note that La₂O₃ has a relatively low electron affinity.

TABLE 2

| | Electron Affinity (eV) | Dielectric Constant |
|---|---|---|
| HfO₂ | 3 | 25 |
| ZrO₂ | 3.1 | 25 |
| Ta₂O₅ | 4.2 | 25 |
| La₂O₃ | 2.2 | 30 |
| TiO₂ | 4.5 | 80 |

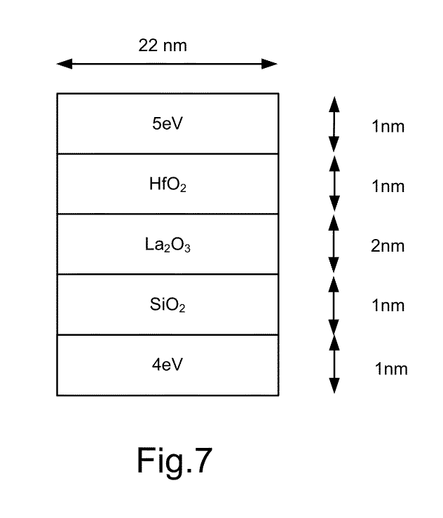

FIG. 7 depicts one embodiment of a MIIIM diode having a region of lanthanum oxide (La₂O₃). The MIIIM diode has electrodes with 4 eV and 5 eV work functions. Each electrode is 1 nanometer thick. The insulating region near the 5 eV electrode is hafnium dioxide and is 1 nanometer thick. The insulating region near the 4 eV electrode is silicon dioxide (SiO₂) and is 1 nanometer thick. Between the other two insulating regions is a region of La₂O₃, which is 2 nm thick. The MIIM diode is 22 nm wide. It is not required that the La₂O₃ region be placed between the two other insulators. In another embodiment, the hafnium dioxide and lanthanum oxide regions are switched from their positions in FIG. 7.

In order to demonstrate the improvements that using a region of lanthanum oxide may have on MIIM diode performance simulations were performed for three MIIM diodes. One is a hafnium oxide based MIIM diode having a configuration such as depicted in FIG. 6A. A second is a lanthanum oxide based MIIM diode having a similar configuration but with the hafnium oxide region replaced with a lanthanum oxide region of the same thickness. A third is for a MIIIM diode having a configuration such as depicted in FIG. 7.

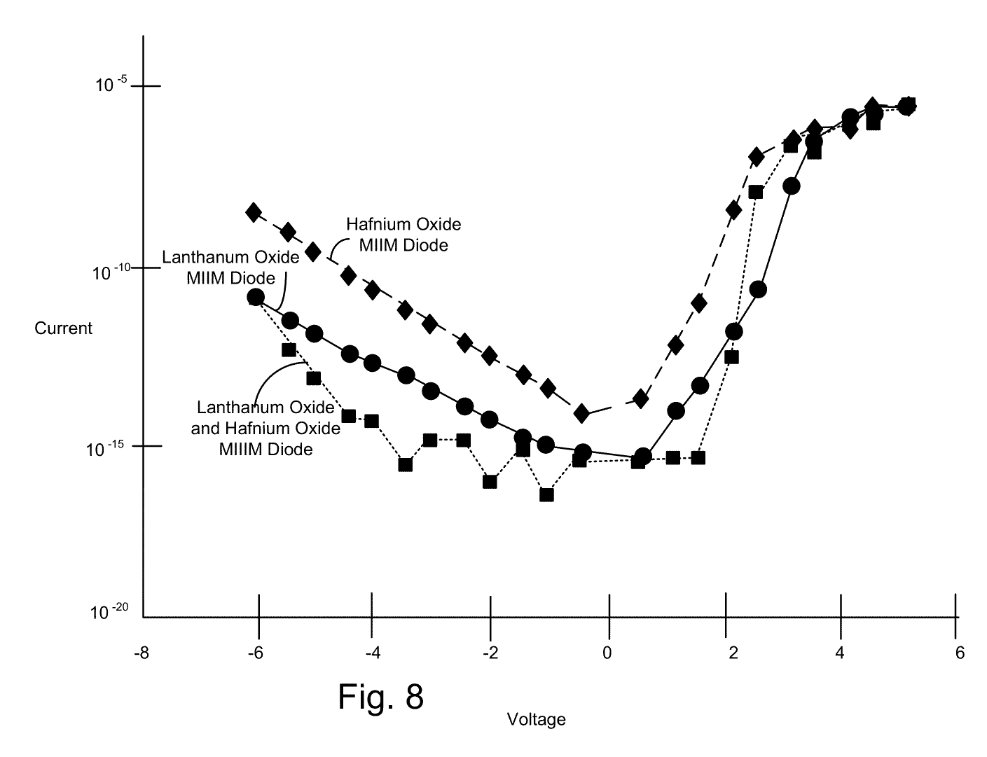

Referring now to FIG. 8, three curves of diode current versus voltage are depicted. One is for the hafnium oxide based MIIM diode, one is for the lanthanum oxide based diode, the third is for a MIIIM diode having a configuration such as depicted in FIG. 7. Note that the leakage current for both the lanthanum oxide MIIM diode and the MIIIM diode are substantially lower than for the hafnium oxide MIIM diode. Also note that for voltages around 5V, the on currents of the three diodes are nearly the same.

Note that the curves for the lanthanum oxide diodes have a very sharp turn on. This may be explained by the relative similarity in the conduction bands of hafnium oxide and lanthanum oxide. For example, the conduction band of hafnium oxide may be slightly lower than the conduction band of lanthanum oxide. This means that at some point the forward bias voltage is just great enough such that electrons do not need to tunnel through the hafnium oxide but the electrons still need to tunnel through the lanthanum oxide. If the voltage is raised slightly, the electrons no longer need to tunnel through either the hafnium oxide or the lanthanum oxide. Hence, there is a very strong increase in current.

Table 3 shows the rectification factor, the on-current, and the leakage current for the curves depicted in FIG. 8.

TABLE 3

| | Lanthanum Oxide | Hafnium Oxide | MIIIM diode |
|---|---|---|---|
| Rectification | 4.6 × 10⁶ | 1.7 × 10⁵ | 9 × 10⁹ |
| Ratio | at +−3.5 V | at +−2.5 V | at +−3.5 V |
| On Current | 2.6 × 10⁻⁶ | 3 × 10⁻⁶ | 3.5 × 10⁻⁶ |
| At 5 V | | | |
| Leakage | 1.1 × 10⁻⁹ | 187 × 10⁻⁹ | 0.06 × 10⁻⁹ |
| Current at −5 V | | | |

The values from Table 3 show that the leakage current for the MIIIM diode at −5V is extremely low compared to the MIIM diodes. Moreover, the on currents at 5V are very similar. Note that the rectification ratio for the MIIIM diode is substantially better than either MIIM diode (note that the rectification ratios were not measured at the same voltages for all diodes). Also note that the effect of traps are not accounted for in the simulation.

One embodiment is a MIIIM diode having the following configuration: metal 1—dielectric 1—dielectric 2—dielectric 1—metal 2. This configuration can be beneficial if dielectric 2 does not form a good interface with, for example, metal 2. Dielectric 1 is selected for its ability to form a good interface with metal 1 and metal 2. Thus, by having dielectric 2 separated from the metals, the problem of a poor dielectric 2/metal interface is avoided. The diode can have a stacked configuration such as depicted in FIG. 7. An example material for metal 1 and metal 2 is titanium nitride. Each metal layer may have a thickness of 10 nm. Dielectric 1 is any insulator that forms a suitable interface with the metals. An example material for dielectric 1 is hafnium oxide. Each layer of hafnium oxide may be 15 nm thick. Any number of insulators could be used for dielectric 2. An example is silicon dioxide. The silicon dioxide may be 10 nm thick.

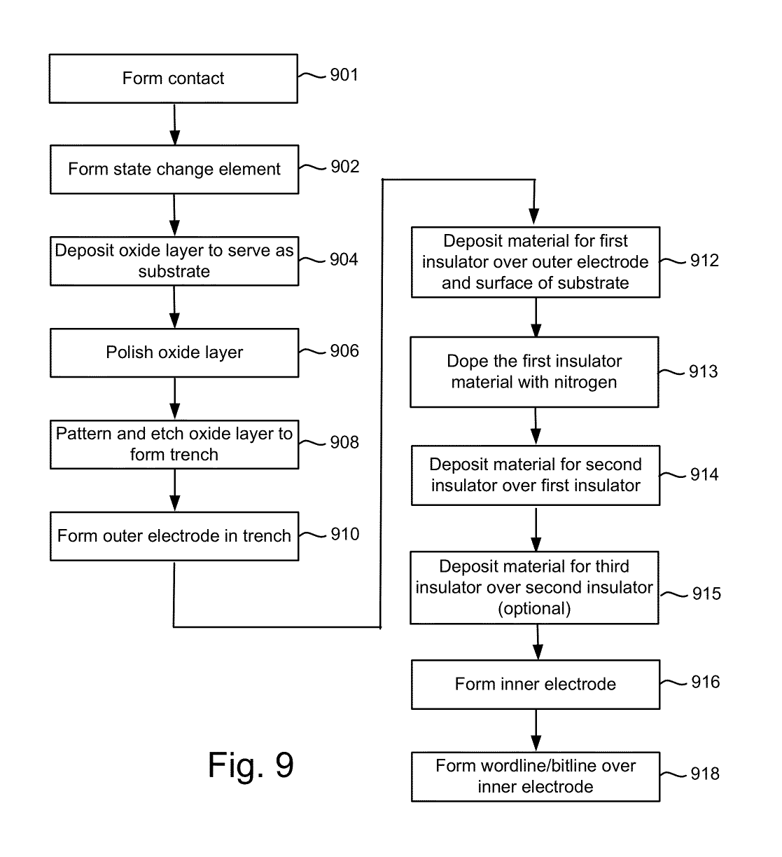

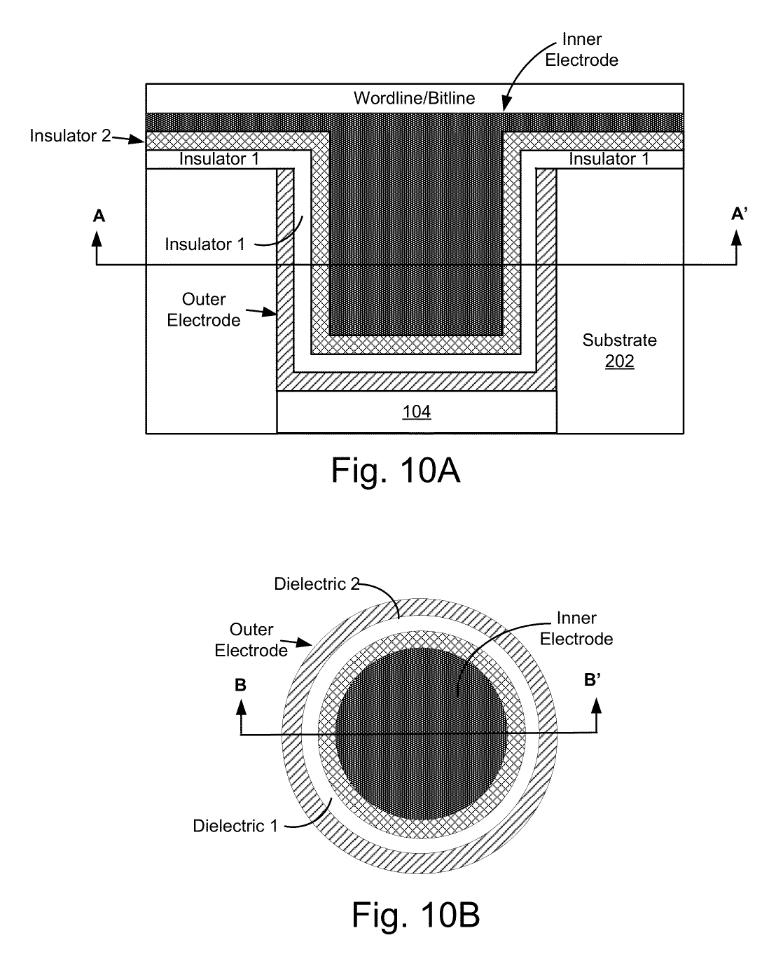

FIG. 9 is a flowchart illustrating steps of one embodiment of a process of forming a MIIM diode. The basic process flow of FIG. 9 can be used to create MIIM diodes having many different shapes. For example, the MIIM diode can comprise layers as depicted in FIG. 2. As another alternative, the MIIM diode can be formed in a trench with an outer electrode and an inner electrode. The insulators are sandwiched between the inner and outer electrodes. FIGS. 10A and 10B depict an example of a trench type MIIM diode. FIG. 10A depicts a cross section of one embodiment of a MIIM diode taken along line B-B′ of FIG. 10B. FIG. 10B depicts a cross section of the embodiment of FIG. 10A taken along line A-A′ of FIG. 10A. The MIIM diode in general comprises an outer electrode, an inner electrode, with two insulators in between. FIG. 10A also depicts a state change element 104 in electrical contact with the inner electrode. This configuration with the inner electrode and outer electrode results in substantial surface area of the electrodes being near each other, given the overall size of the MIIM diode. The large substantial surface area results in a substantial on-current.

In the embodiment of FIG. 10B, the cross section of the MIIM diode is depicted as having a generally circular shape. However, the MIIM diode can have many other shapes along that cross section. For example, the cross section could be an ellipse or a polygon with any number of sides. If the cross section is a polygon it is not required that the corners be sharp. For example, the polygon could have rounded corners. Other shapes could also be used, such as a star shape. Thus, the cross section is not limited to a particular shape.

Further, while FIG. 10B depicts the outer electrode as completely surrounding the inner electrode (and insulators) with respect to the cross section shown in FIG. 10B, this is not a requirement.

In the embodiment depicted in FIGS. 10A-10B, the MIIM diode is disposed within a trench in a substrate 202. The trench is not explicitly shown in FIGS. 10A-10B. However, the outer electrode is formed in the trench. Therefore, the general shape of the trench can be understood as the outer bounds of the outer electrode, in this embodiment. In general, the trench has a bottom and sidewalls. The bottom of the trench is the line that touches the bit line contact. As depicted in FIG. 10A, the sidewalls are vertical and are substantially perpendicular to the bottom. Thus, the outer electrode (and other elements) has substantially the same width from top to bottom in FIG. 10A. However, it is not required that the sidewalls of the trench be substantially perpendicular to the bottom of the trench. For example, the sidewalls could be wider near the top than near the bottom. Thus, the width of the outer electrode (and other elements) could become progressively wider nearer the top.

Further details of trench type of MIIM diodes are described in U.S. patent application Ser. No. 12/240,785 to Sekar, entitled, “MIIM DIODES HAVING STACKED STRUCTURE.”

Referring now to the flowchart in FIG. 9, in step 901, a wordline/bitline contact is formed. In one implementation, the wordline/bitline contact is formed from TiN. However, another material may be used. The formation of the wordline/bitline contact can be achieved by depositing TiN and patterning and etching. The wordline/bitline contact forms an electrical connection to either a word line or a bit line, which may be formed from tungsten, aluminum, or another conductor.

In step 902, a state change element 104 is formed. Many different types of state change elements can be formed in this step. As one example, a GST state change element is formed. In one aspect, the GST state change element is set to either a crystalline (conductive) state or an amorphous (high resistance) state in step 902. The state of the GST state change element is controlled by heating to an appropriate temperature for an appropriate time. The heating can be achieved by passing a current through the GST state change element. For example, a GST state change element may be transformed into an amorphous (high resistance) state by heating the GST state change element to a melting temperature, and then fast quenching the phase-change material GST. Rapid cooling of the material to below its glass transition temperature causes the GST state change element to be locked into its amorphous phase. During operation of the memory device, in order to switch the GST state change element back to its conductive state, the GST state change element may be heated to at least its crystallization temperature (which is between the glass transition temperature and the melting temperature). This heating causes nucleation and crystal growth to rapidly occur over a period of several nanoseconds. The crystallization temperature is maintained for a period of time that is sufficient to allow the formation of crystals in the GST state change element.

Note that many other types of state change elements 104 could be formed in step 902. Examples of other state change elements 104 have already been provided herein. Step 902 may form any of those example state change elements, or other state change elements 104 not specifically mentioned herein.

In step 904, an oxide layer is deposited above and around the state change element 104. The oxide layer will serve as the substrate 202. In step 906, the oxide layer is polished to smooth the surface of the oxide. For example, chemical mechanical polishing (CMP) is performed.

In step 908, the oxide layer is patterned and etched to form a trench in the oxide layer. The etch may be isotropic or anisotropic. Etches that are more isotropic could help reduce the burden on the lithography while contacting the inner electrode and also make the device more scalable. An example width for the trench is 22 nanometers. An example depth for the trench is 70 nanometers. However, the trench could have a different width and/or a different depth. Also, note that the aspect ratio of the trench could be higher or lower than this example.

In step 910, an outer electrode is formed in the trench. In one aspect, the outer electrode is formed using atomic layer deposition (ALD). However, other techniques can be used to form the outer electrode. After depositing the material for the outer electrode excess material that is outside of the trench is removed. Thus, diodes in different trenches are electrically isolated. In one implementation, polishing (e.g., CMP) is performed to result in the electrode covering the bottom and sidewalls of the trench. However, the outer electrode does not cover the top surface of the substrate 202. In another implementation, excess electrode material is removed by etching. The outer electrode has an outer surface (in contact with substrate 202 and state change element 104) and an inner surface. The inner surface defines a region within the outer electrode.

In one implementation, the outer electrode is formed from titanium nitride. In one implementation, the work function of the outer electrode is tuned by addition of a suitable material. For example, aluminum is added to tune the work function. If the outer electrode is to serve as the cathode of the diode, the work function could be established at 4 eV, as an example. If the outer electrode is to serve as the anode, the work function could be established at 5 eV, as an example. Note that in this example, the cathode is established with a lower work function than the anode. Other values that 4 eV and 5 eV could also be used. It is not a requirement that the cathode have a lower work function than the anode. In another aspect, the anode and cathode have the same work function. In still another aspect, the cathode has a higher work function than the anode.

It is not required that the outer electrode be formed from titanium nitride. In one implementation, a diode is formed in which the outer electrode is formed from polysilicon that has been treated to increase its conductivity. As an example, the outer electrode is formed from doped polysilicon. For example, the outer electrode could be n+ doped polysilicon or p+ doped polysilicon. The polysilicon can be treated in other ways to increase its conductivity. Herein, the term metal insulator diode is intended to include diodes whose electrodes are formed from polysilicon.

In step 912, a first insulator layer is formed. A portion of the first insulator is deposited as a conformal layer over the inner surface of the outer electrode. Another portion of the first insulator is deposited over the surface of the substrate 202. In one aspect, the first insulator is formed using atomic layer deposition (ALD). However, other techniques can be used to form the first insulator. The first insulator may be formed from silicon dioxide. As an example, the first insulator can be about 10 Angstroms thick. The first insulator may have roughly the same thickness on the bottom of the trench as on the sides. However, it is not a requirement that the first insulator have a uniform thickness. In one embodiment, the first insulator is a high band gap insulator such as SiO₂.

In step 913, the first insulator material is doped with nitrogen. For example, nitrogen ions can be implanted in the second insulator at a depth and concentration that is controlled by the energy and dose of nitrogen. The energy at which the ions are implanted controls the depth. In one embodiment, the dopant is a material other than nitrogen. Thus, after doping the first insulator is SiON. The amount of oxygen and nitrogen can be selected as previously described herein.

In step 914, a second insulator layer is formed. A portion of the second insulator is deposited as a conformal layer over the portion of the first insulator that is within the trench. Another portion of the second insulator is deposited over the portion of the first insulator that extends over the substrate surface. In one aspect, the second insulator is formed using atomic layer deposition (ALD). However, other techniques can be used to form the second insulator. The second insulator may be formed from hafnium dioxide. As an example, the second insulator can be about 20 Angstroms thick. The second insulator may have roughly the same thickness on the bottom of the trench as on the sides. However, it is not a requirement that the second insulator have a uniform thickness. In one embodiment, the second insulator is a low band gap insulator such as HfO₂. In an embodiment in which three insulator layers are used, the second insulator may be LaO₃.

In optional step 915, a third insulator is formed over the second insulator. In one embodiment, the third insulator is a low band gap insulator such as HfO₂. When using a third insulating layer, the third insulating layer may be about 10 Angstroms thick.

In step 916, the inner electrode is formed. A portion of the inner electrode is formed within the trench. Another portion of the inner electrode is formed over the portion of the second insulator that extends over the substrate surface. The inner electrode may be formed from titanium nitride. However, other materials can be used to form the inner electrode. The material for the inner electrode may be depositing using many different techniques. In one aspect, the inner electrode is formed using atomic layer deposition (ALD). However, it is not required that the inner electrode be deposited as a very thin layer, hence ALD is not required for forming the inner electrode. After depositing the material, polishing (e.g., CMP) is performed.

In one aspect, the inner electrode serves as the anode and has work function of 5 eV with the outer electrode serving as the cathode with a work function of 4 eV. In another aspect, the inner electrode serves as the cathode and has work function of 4 eV with the outer electrode serving as the anode with a work function of 5 eV.

In step 918, a wordline/bitline is formed over top of the inner electrode. The wordline/bitline may be formed from Aluminum, although other materials could be used. Step 918 includes depositing the material for the wordline/bitline, patterning, and etching. Techniques for patterning and etching wordlines/bitlines are well known and will not be discussed in detail. The result after performing step 918 is depicted in FIG. 10A.

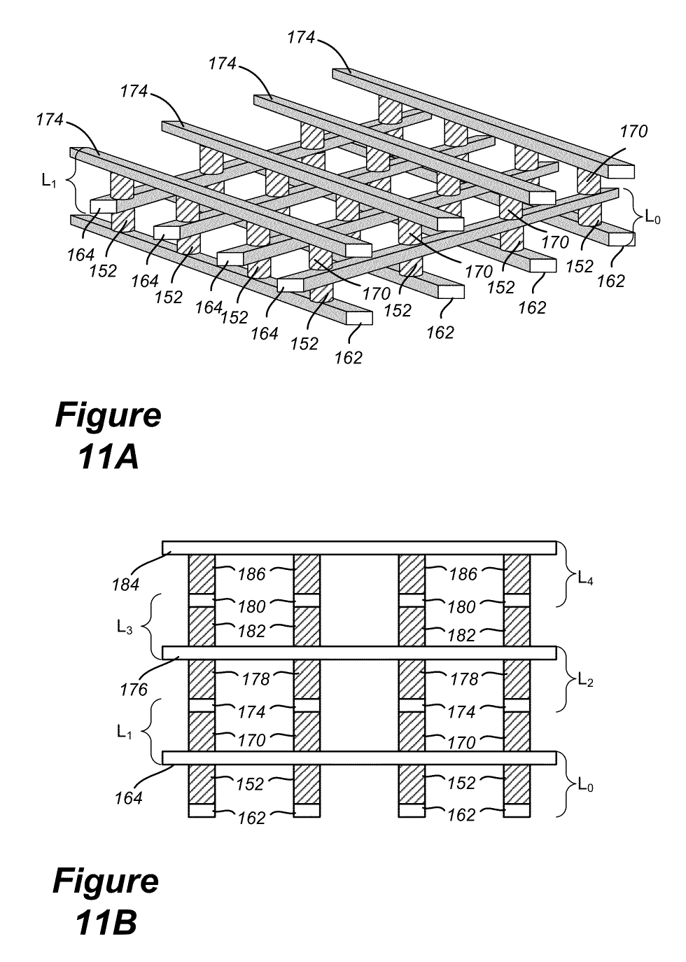

FIGS. 11A-11B depict a portion of an exemplary monolithic three-dimensional memory array that can be used in various embodiments. However, other memory structures can be used in accordance with various embodiments, including two-dimensional memory structures manufactured on, above, or within a semiconductor substrate. Both the word line and bit line layers are shared between memory cells in the structure depicted in the perspective view of FIG. 11A. This configuration is often referred to as a fully mirrored structure. A plurality of substantially parallel and coplanar conductors form a first set of bit lines 162 at a first memory level L0. Memory cells 152 at level L0 are formed between these bit lines and adjacent word lines 164. In the arrangement of FIGS. 11A-11B, word lines 164 are shared between memory layers L0 and L1 and thus, further connect to memory cells 170 at memory level L1. A third set of conductors form the bit lines 174 for these cells at level L1. These bit lines 174 are in turn shared between memory levels L1 and memory level L2, depicted in the cross-sectional view of FIG. 11B. Memory cells 178 are connected to bit lines 174 and word lines 176 to form the third memory level L2, memory cells 182 are connected to word lines 176 and bit lines 180 to form the fourth memory level L3, and memory cells 186 are connected to bit lines 180 and word lines 184 to form the fifth memory level L5. The arrangement of the diodes' polarity and the respective arrangement of the word lines and bit lines can vary by embodiment. Additionally, more or fewer than five memory levels can be used.

In one embodiment, the MIIM diodes of memory cells 170 are formed upside down relative to the MIIM diodes of the first level of memory cells 152. For example, referring to electrode 1 and electrode 2 in FIG. 2A, electrode 1 is closest to conductor 164 for cells 170, whereas electrode 1 is closest to conductor 164 for cells 152.

In an alternative embodiment, an inter-level dielectric can be formed between adjacent memory levels. In this alternative, no conductors are shared between memory levels. This type of structure for three-dimensional monolithic storage memory is often referred to as a non-mirrored structure. In some embodiments, adjacent memory levels that share conductors and adjacent memory levels that do not share conductors can be stacked in the same monolithic three dimensional memory array. In other embodiments, some conductors are shared while others are not. For example, only the word lines or only the bit lines can be shared in some configurations. A first memory level L0 can include memory cells between a bit line level BL0 and word line level WL0. The word lines at level WL0 can be shared to form cells at a memory level L1 that connect to a second bit line level BL1. The bit line layers are not shared so the next layer can include an interlayer dielectric to separate bit lines BL1 from the next level of conductors. This type of configuration is often referred to as half-mirrored. Memory levels need not all be formed having the same type of memory cell. If desired, memory levels using resistive change materials can alternate with memory levels using other types of memory cells, etc.

In one embodiment as described in U.S. Pat. No. 7,054,219, entitled, “Transistor Layout Configuration for Tight Pitched Memory Array Lines,” word lines are formed using word line segments disposed on different word line layers of the array. The segments can be connected by a vertical connection to form an individual word line. A group of word lines, each residing on a separate layer and substantially vertically-aligned (notwithstanding small lateral offsets on some layers), may be collectively termed a row. The word lines within a row preferably share at least a portion of the row address. Similarly, a group of bit lines, each residing on a separate layer and substantially vertically-aligned (again, notwithstanding small lateral offsets on some layers), may be collectively termed a column. The bit lines within a column preferably share at least a portion of the column address.

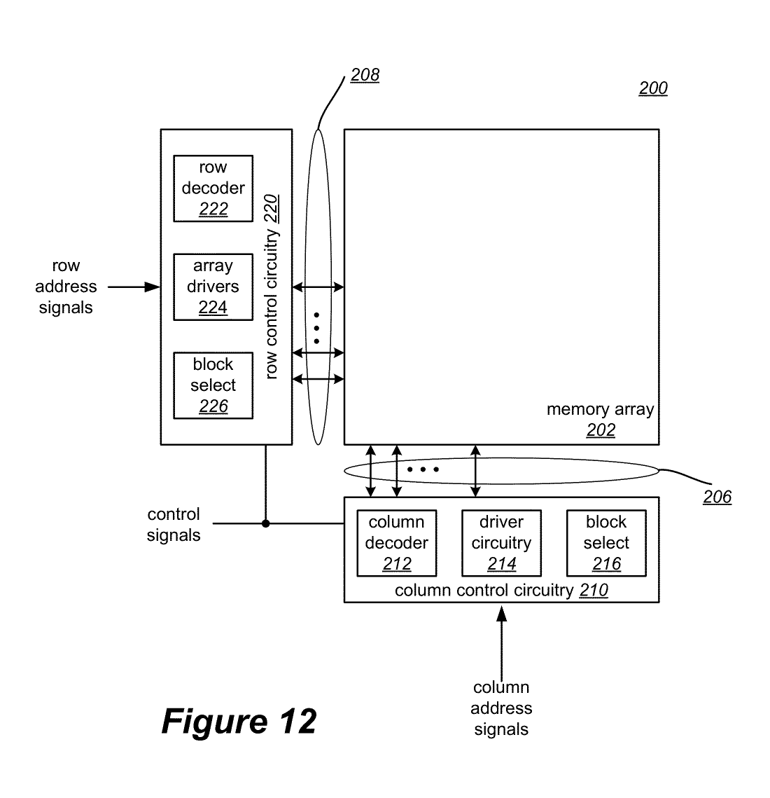

FIG. 12 is a block diagram of an integrated circuit including a memory array 202. The array terminal lines of memory array 202 include the various layer(s) of word lines organized as rows, and the various layer(s) of bit lines organized as columns. The integrated circuit 200 includes row control circuitry 220 whose outputs 208 are connected to respective word lines of the memory array 202. The row control circuitry receives a group of M row address signals and one or more various control signals, and typically may include such circuits as row decoders 222, array terminal drivers 224, and block select circuitry 226 for both read and write (i.e., programming) operations. The integrated circuit 200 also includes column control circuitry 210 whose input/outputs 206 are connected to respective bit lines of the memory array 202. The column control circuitry 206 receives a group of N column address signals and one or more various control signals, and typically may include such circuits as column decoders 212, array terminal receivers or drivers 214, block select circuitry 216, as well as read/write circuitry, and I/O multiplexers. Circuits such as the row control circuitry 220 and the column control circuitry 210 may be collectively termed control circuitry or array terminal circuits for their connection to the various array terminals of the memory array 202.

Integrated circuits incorporating a memory array usually subdivide the array into a sometimes large number of sub-arrays or blocks. Blocks can be further grouped together into bays that contain, for example, 16, 32, or a different number of blocks. As frequently used, a sub-array is a contiguous group of memory cells having contiguous word and bit lines generally unbroken by decoders, drivers, sense amplifiers, and input/output circuits. This is done for any of a variety of reasons. For example, the signal delays traversing down word lines and bit lines which arise from the resistance and the capacitance of such lines (i.e., the RC delays) may be very significant in a large array. These RC delays may be reduced by subdividing a larger array into a group of smaller sub-arrays so that the length of each word line and/or each bit line is reduced. As another example, the power associated with accessing a group of memory cells may dictate an upper limit to the number of memory cells which may be accessed simultaneously during a given memory cycle. Consequently, a large memory array is frequently subdivided into smaller sub-arrays to decrease the number of memory cells which are simultaneously accessed. Nonetheless, for ease of description, an array may also be used synonymously with sub-array to refer to a contiguous group of memory cells having contiguous word and bit lines generally unbroken by decoders, drivers, sense amplifiers, and input/output circuits. An integrated circuit may include one or more than one memory array.

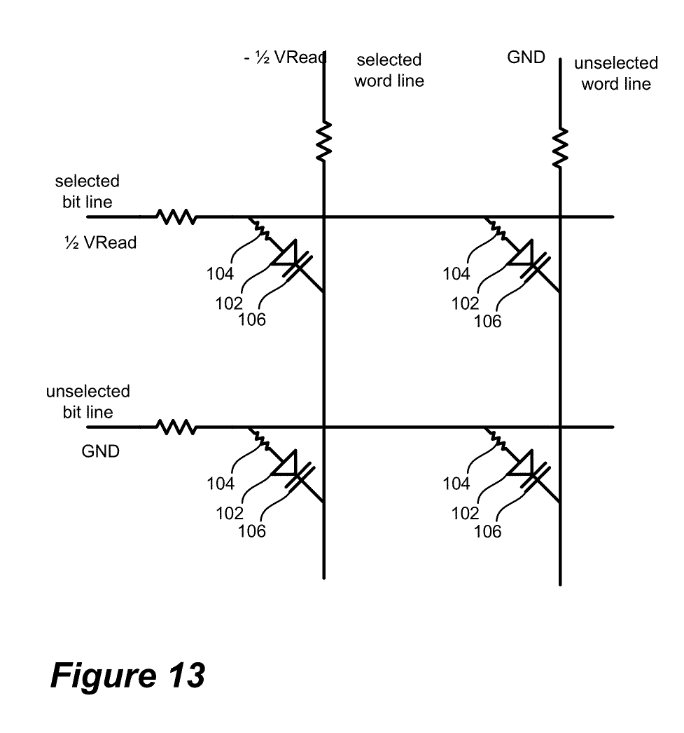

FIG. 13 is a circuit diagram of a portion of a memory array during operation in accordance with one embodiment. Various biasing schemes can be used to program and read the memory cells. The following describes details of some implementations, but it not intended to be limiting. In some implementations, memory cells are programmed or read by establishing an appropriate voltage across the memory element by application of suitable voltages to the word lines and bit lines.

For example, to read a memory cell, selected bit lines may be set to a positive bias (e.g., ½ Vread) with unselected bit lines grounded. Selected word lines may be set to at a negative bias (e.g., −½ Vread) with unselected word lines grounded. Thus, a selected memory cell will have Vread across it. Other bias conditions may also be used to read the memory cells.

In some embodiments, the state change element is formed from carbon. In these embodiments, memory cell operation may be based on a bi-stable resistance change in the carbon material with the application of high bias voltage (e.g., 4 V). The difference in resistivities between the two states may be over 100×, as described in U.S. Pat. No. 6,706,402. Current through the memory cell is a function of the resistance of the carbon material. The memory cells are read at a lower voltage than the program voltage such that reading will not change the resistance of the carbon material. The memory cell may be changed from a “0” to a “1” with the application of high forward bias on the diode. The memory cell may be changed back from a “1” to a “0” with the application of a high forward bias.

The details of operating the memory cells will vary depending on the embodiment. The following describes other details of operating some embodiments of memory cells. During integrated circuit manufacturing, the state change element of the memory cell may be placed in a certain one of its possible states; this is called the “initial state.” For example, if the state change element is a dielectric-rupture anti-fuse having the two states (ruptured dielectric) and (intact dielectric), the initial state of this element is (intact) after manufacturing and before programming. Other embodiments of state change elements will have different sets of states and thus different initial states. By convention this initial state, the “logic zero” state denotes the initial value stored in the memory cell during semiconductor manufacturing. But of course other conventions, calling the initial state e.g. “logic one,” would be equally valid, and the choice is merely a matter of preference or convenience rather than technological necessity.

The memory cell is programmed by causing the state change element to transition from its initial state into a new state. Many embodiments of the state change element can be caused to change state by applying a suitably large voltage across the memory cell, from input terminal to output terminal. For example, if the state change element is embodied as a dielectric-rupture antifuse, it may be programmed by applying a large voltage across the cell's terminals (or by forcing a large current through the cell), with the polarity chosen such that the steering element is forward biased. This places a large electric field directly across the dielectric antifuse, which ruptures the dielectric, thus changing the state of the state change element.

One possible method for programming a dielectric-rupture state change element is to ground the memory cell's output terminal and simultaneously raise its input terminal to a large positive voltage (assuming the steering element is so oriented that its anode faces the input terminal and its cathode faces the output terminal, i.e., steering element is forward biased when the input terminal is at a higher voltage than the output terminal). If the steering element is oriented the other way, with anode facing the output terminal and cathode facing the input terminal, the designer can simply reverse the programming voltages and keep the steering element forward biased during programming: ground the input terminal and simultaneously raise the output terminal to a large positive voltage. Many other voltage arrangements for forward biasing the steering element and programming a dielectric-rupture state change element will be readily apparent to those skilled in the art.

Other embodiments of the state change element can be caused to change state by forcing a suitably large current through the memory cell, rather than forcing a large voltage across the memory cell. For example, if the state change element is embodied as a polysilicon-resistor fuse, it may be programmed by connecting a current source to its input terminal and simultaneously grounding its output terminal (assuming this polarity forward biases the steering element). Assuming the current is large enough, it alters the resistance of the polysilicon-resistor fuse, thus changing the state of the state change element and programming the cell.

During programming, it is possible for nonselected memory cells to be reverse-biased by the full programming voltage. Accidental writes of nonselected memory cells might occur, if the reverse leakage current of the steering element exceeded the programming current necessary to change the state of the state change element. Thus, the characteristics of the steering and state change elements should be matched to one another; a state change element that requires a large current to program (e.g., an intrinsic poly fuse) can be used with a rather high-leakage steering element, while a state change element that programs at very low current (e.g., a dielectric rupture antifuse) requires a low-leakage steering element.

The memory cell can be embodied either as a one-time programmable nonvolatile memory, or as a write/erase/rewrite nonvolatile memory, depending on the state change element selected. In a first example, if a thin, highly resistive, polycrystalline silicon film antifuse is employed as the state change element (as taught in U.S. Pat. No. 4,146,902), its programming operation is irreversible and the cell is one-time programmable. After manufacturing and before programming, all cells contain “logic zero”. Those cells whose desired contents are “logic one” are programmed, irreversibly, by forcing the state change element into a new state. Logic zeroes may become logic ones (by programming), but logic ones may NOT become logic zeroes (since programming is irreversible in this type of state change element).

In a second example, if a metal-via-insulator-silicon filament fuse is employed as the state change element (as taught in U.S. Pat. No. 3,717,852), its programming operation is reversible and the cell may be written, erased, and rewritten. After manufacturing and before programming, all cells contain “logic zero”. Those cells whose desired contents are “logic one” are programmed. However, for this state change element, programming is reversible and logic values may be changed from zero to one and back from one to zero, if desired.

In a third example, a state change element having a write/erase/rewrite capability may be employed, whose programming operation is electrical but whose erase operation is not necessarily electrical. The erase operation may be selectively applied to a single memory cell, or it may be applied to all memory cells at once, “in bulk,” such as by exposing them to a strong source of ultraviolet light as is done with UVEPROM memories. Or a bulk erase operation may be initiated by heating the integrated circuit, either from a heat source external to the IC or from a heater directly on the IC. Or a bulk erase might be initiated by placing the state change elements in a strong magnetic field.

While the above discussion is based on a state change element that has two states, this is not necessary. An antifuse that can provide a predetermined range of resistance where for instance it is partly fused, would provide a three state element. A floating gate MOS device allows numerous possible implementations of multi-level storage, providing more than 2 states for a state change element, as is well known in the art.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

What is claimed is:

1. A metal-insulator diode comprising:
a first metal electrode;
a first region comprising a first insulator material having an interface with the first metal electrode;
a second region comprising a second insulator material having an interface with the first insulator material;
a third region comprising a third insulator material having an interface with the second insulator material; and
a second metal electrode having an interface with the third insulator material, at least one of the first, second, or third insulator materials is lanthanum oxide.

2. The diode of claim 1, wherein:
at least one of the first insulator material, the second insulator material, or the third insulator material is hafnium oxide.

3. The diode of claim 1, wherein the first insulator material is hafnium oxide and the second insulator material is lanthanum oxide.

4. The diode of claim 3, wherein the third insulator material is silicon oxide.

5. The diode of claim 3, wherein the first region is approximately 10 angstroms thick and the second region is approximately 20 angstroms thick.

6. The diode of claim 1, wherein the first insulator material is lanthanum oxide and the second insulator material is hafnium oxide.

7. The diode of claim 5, wherein the first region is approximately 20 angstroms thick and the second region is approximately 10 angstroms thick.

8. The diode of claim 1, wherein the first metal electrode has a higher work function than a work function of the second metal electrode.

9. A method for forming a metal-insulator diode comprising:
forming a first metal electrode;
forming a first region comprising a first insulator material having an interface with the first metal electrode;
forming a second region comprising a second insulator material having an interface with the first insulator material;
forming a third region comprising a third insulator material having an interface with the second insulator material; and
forming a second metal electrode having an interface with the third insulator material, at least one of the first, second, or third insulator materials is lanthanum oxide.

10. The method of claim 9, wherein:
at least one of the first insulator material, the second insulator material, or the third insulator material is hafnium oxide.

11. The method of claim 9, wherein the first insulator material is hafnium oxide and the second insulator material is lanthanum oxide.

12. The method of claim 11, wherein the first region is approximately 10 angstroms thick and the second region is approximately 20 angstroms thick

13. The method of claim 9, wherein the third insulator material is silicon oxide.

14. The method of claim 9, wherein the first insulator material is lanthanum oxide and the second insulator material is hafnium oxide.

15. The method of claim 14, wherein the first region is approximately 20 angstroms thick and the second region is approximately 10 angstroms thick.

16. The method of claim 9, wherein the first metal electrode has a higher work function than a work function of the second metal electrode.

17. The method of claim 9, further comprising forming a memory element electrically coupled to the diode in series.

18. A non-volatile storage element, comprising:
a metal-insulator-insulator-insulator-metal (MIIIM) diode, including:
a first electrode comprising a first metal;
a first region comprising a first insulating material, the first insulating material is hafnium oxide;
a second region comprising a second insulating material;
a third region comprising a third insulating material, the third insulating material is lanthanum oxide, the hafnium oxide has an interface to the lanthanum oxide; and
a second electrode comprising a second metal, the first region, the second region, and the third region reside between the first electrode and the second electrode; and
a state change element electrically coupled to the MIIIM diode in series.

19. The diode of claim 18, wherein the third region is between the first region and the second region.

20. The diode of claim 18, wherein the first region is between the second region and the third region.
